(19) United States
(12) Patent Application Publication
(10) Pub. No.: US 2008/0043405 A1
(43) Pub. Date: Feb. 21, 2008

(54) CHASSIS PARTITION ARCHITECTURE FOR MULTI-PROCESSOR SYSTEM

(75) Inventors: Mario J.D. LEE, Fremont, CA (US); Tomonori HIRAI, Fremont, CA (US); Jyh Ming JONG, Fremont, CA (US)

Correspondence Address: APEX JURIS, PLLC;TRACY M HEIMS, LAKE CITY CENTER, SUITE 410, 12360 LAKE CITY WAY NORTHEAST, SEATTLE, WA, 98125, US

(73) Assignee: TYAN COMPUTER CORPORATION, Taipei (TW)

(21) Appl. No.: 11/687,571

(22) Filed: Mar. 16, 2007

Related U.S. Application Data
(60) Provisional application No. 60/822,543, filed on Aug. 16, 2006.

(51) Int. Cl. H05K 7/00; H02B 1/00; G06F 1/16; H05K 5/00

(52) U.S. Cl. 361/600; 361/684

(57) ABSTRACT

A chassis partition architecture of a chassis for configuring a multi-processor system is provided to fulfill flexibility, serviceability and configurability of a multi-processor system. The partition architecture mainly includes the partition architecture mainly includes a node partition, a expansion partition and a function partition. The node partition is located at a middle section of the chassis, mainly for containing several processor boards that are configured vertically and lengthwise. The expansion partition is located behind the node partition, mainly for containing several expansion boards that are configured vertically and lengthwise. And the function partition is located at a front section of the chassis lower than the node partition and the expansion partition, mainly for containing a plurality of function cards that are configured upside-down vertically and lengthwise.

### BACKGROUND OF THE INVENTION

1. Related Applications

This application is a non-provisional application of the U.S. provisional application Ser. No. 60/822,543 to Lee et al., entitled “Highly Compact, Integrated, Modular Computer Design with All Serviceable Parts without Internal Cables and Improved Cooling” filed on Aug. 16, 2006.

2. Field of Invention

The present invention relates to chassis space arrangement of electrical apparatus, and more particularly, to a chassis partition architecture for a multi-processor system.

3. Related Art

Chassis space arrangement is always a significant issue for computing systems. Generally, physical hardware architecture determines space arrangement of the chassis. And oppositely the chassis needs to provide necessary mechanical supports for all the electrical units and modules involved in the computing system. Therefore, well-designed hardware architecture always accompanies with a corresponding chassis that has excellent partition architecture.

For a multi-processor system with processors configured on plural printed circuit boards, traditional design of electronic enclosure requires a complex and expensive internal chassis with many routed cables therein to provide mechanical support for the electronic components. The requirements for variable types of input/output devices and storage unit, including hot swapping plus airflow for cooling, further increase the complexity of the system design. This complexity increases the overall sides of the system and in some cases limits some configurable options to become part of the “base architecture”, which is dictated by the overall dimensions of the chassis and internal structure. One example is the difficulty in servicing the center interconnecting plane. Most backplane and mid-plane designs in the prior art are not field serviceable due to difficulty or no access in the assembled chassis. Another example is the difficulty to provide sufficient cooling and airflow to the various components due to blockage as a result of the placement of the different parts of the system. Besides, once numerous function cards need to be configured on the system, it becomes much more difficult to fulfill the requirements of cooling, serviceability and hardware reliability. For high-end systems, flexibility will be another critical issue.

Basically, in the aspects of hardware architecture, there are two major factors to decide the configurable directions or serviceability of a computing system. First of all, the way of physical hardware division decides how the hardware components of the computing system are separated to configure on subsystem boards. Expansion cards and switch boards are also common. The other is the connection types between these subsystem boards. Both the physical division for hardware components and the connection types of subsystem boards affect the cooling performance and hardware reliability. Theoretically the more the subsystem boards are divided, the higher the system flexibility will be; however, the physical division is still limited by actual hardware capabilities.

The chassis partition will need to provide spaces to contain these boards and cards, make openings according to the configurable directions or serviceability, and meanwhile create internal channels to allow interconnecting between boards, cards or even cables. Nevertheless, cooling design is also an important requirement to fulfill.

As shown in FIGS. 1a and 1b, the front portion in a chassis 10 of a clustering system is configured with plural mainboards (mother boards) 11. The chassis 10 is divided into a mainboard partition P10, a fan partition P11, a power partition P12 and a reserved partition P13. The lower half of the rear portion in the chassis 10 (the power partition P12) is configured with one or more power supply 12 that has dedicated fan(s); however, the power supply 12 at the lower portion is still a blockage for the main air flow generated by several main fans 13 at the upper portion. Since the airflow has to pass the power supply 12 through small fan(s), the flow rate through the power supply 12 is usually smaller than the main fans 13. Therefore, the processors 110 are configured at upper positions of mainboard partition P10. In such simple system, the mainboards 11 slides inwards/outwards through the front side of the mainboard partition P10 so it is only front-side serviceable and configurable. Generally the mainboard partition P10 has predetermined access holes or openings to allow human hands reaching inside.

FIG. 2 shows an 8-way system with two stacked mainboard partitions P20, P21, four fan partitions P22, a hard drive partition P23 and a power partition P24. Four processors 210 with dedicated system memories 211 are configured on each of the two stacked processor boards 21. Between the two processor boards 21, two system bus cards 22 are used for board-to-board connection through connectors 212. Such system obviously is top-side serviceable and configurable due to its hardware architecture. Engineers have to remove the upper processor boards 21 from the mainboard partition P20 to access the lower processor boards 21 and the two system bus cards 22 in the mainboard partition 21.

FIG. 3 shows another 8-way system 3, which includes four dual-processor cards 31 configured on a baseboard 32, and an input/output board 33 engaged with the baseboard 32 through several edge connectors 34. The corresponding chassis partition architecture includes a processor partition P31, an input/output partition P32, two fan partition P33, a hard drive partition P34 and a power partition P35. Each of the four dual-processor cards 31 faces another two by two, with one or more fan 35 configured between each pair of four dual-processor cards 31. Expansion card(s) 331, I/O controller(s) 332 and bridge chips 333 are located on the input/output board 33. The cooling problem in such “flat” system is that the sizes of the fans 35 is relatively smaller, which require high rotation speed to carry away the heat efficiently. However, the higher the fan speed increases, the more the fan noise occurs. Besides, although such system has overall two or three serviceable/configurable sides (the two lengthwise sides and the top side), the cooling, serviceability and reliability problems will still occur when extra function cards (not shown) are added on the system architecture.

When a lot more expansion cards or functions cards are required, the chassis partition will become much more complicated. If the extra function cards are arranged lengthwise (following the directions of the dual-processor cards 31), the system will need an extra partition and has a strange flat, long structure. Besides, the flow paths will be too long to dissipate heat efficiently. If the extra function cards are arranged widthwise (parallel to the expansion card(s) 331), the trace lengths on the input/output board 33 might be too long to meet bus communication requirements. Plus the arrangement of blockage units like hard drives, the architecture becomes extremely complicated.

### SUMMARY OF THE INVENTION

Accordingly, the present invention basically provides an optimum chassis partition architecture for a multi-processor system like clustering system. In an embodiment of the present invention, the partition architecture of a chassis for configuring a multi-processor system mainly includes a node partition, a expansion partition and a function partition. The node partition is located at a middle section of the chassis for containing plural processor boards configured vertically and lengthwise. The expansion partition is located behind the node partition for containing plural expansion boards configured vertically and lengthwise. And the function partition is located at a front section of the chassis lower than the node partition and the expansion partition for containing a plurality of function cards configured upside-down vertically and lengthwise.

In an embodiment of the present invention, a bottom plane of the multi-processor system facing upwards and is configured under the node partition and the expansion partition to allow the processor boards and the expansion cards connecting thereon. Besides, a function board facing downwards is configured in an edge-to-edge connection with a front edge of the bottom plane to allow the function cards configured downwards and lengthwise on a bottom surface of the function board.

In an embodiment of the present invention, the node partition exceeds to reach the top of the function partition.

In an embodiment of the present invention, the architecture further includes a main space and an sub-space, each provided with a dedicated airflow; wherein the main space includes the node partition and the expansion partition and the sub-space includes the function partition. In some cases, the main space further includes a main-fan partition located right in front of the node partition for containing one or more main system fan. The main space may further include a storage partition located behind the node partition and on the top of the expansion partition for containing several hard drives. On the other hand, the sub-space may further include a sub-fan partition located behind the function partition for containing one or more auxiliary system fan. In certain conditions, the sub-space may further include a power partition located behind the sub-fan partition for containing some power supplies.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow illustration only, and thus are not limitative of the present invention, and wherein:

FIG. 1a shows an explanatory diagram for the hardware architecture of a clustering system in the prior art.

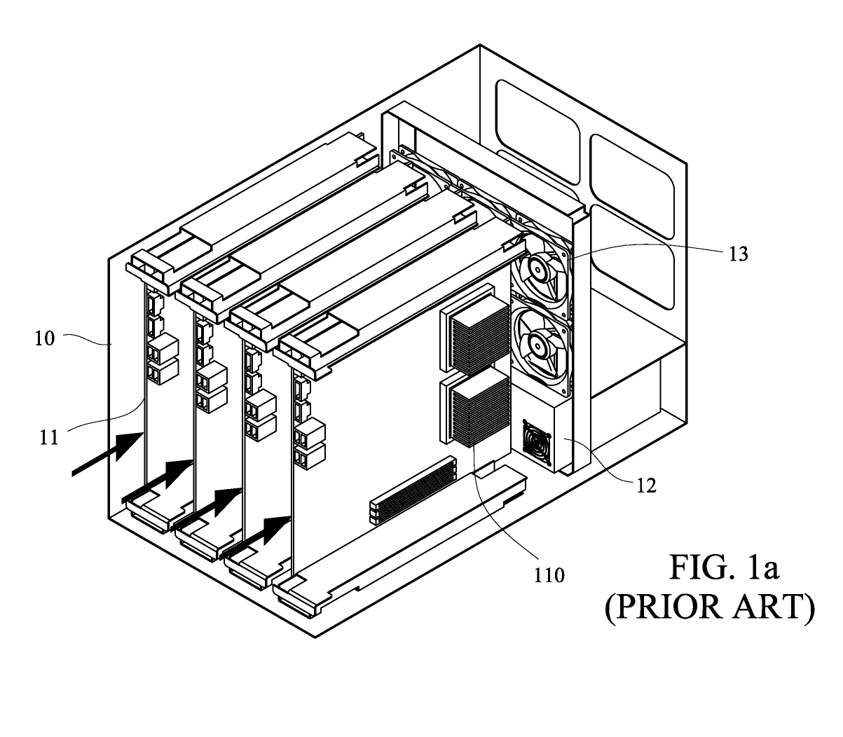

FIG. 1b shows an explanatory diagram of a chassis partition architecture according to FIG. 1a.

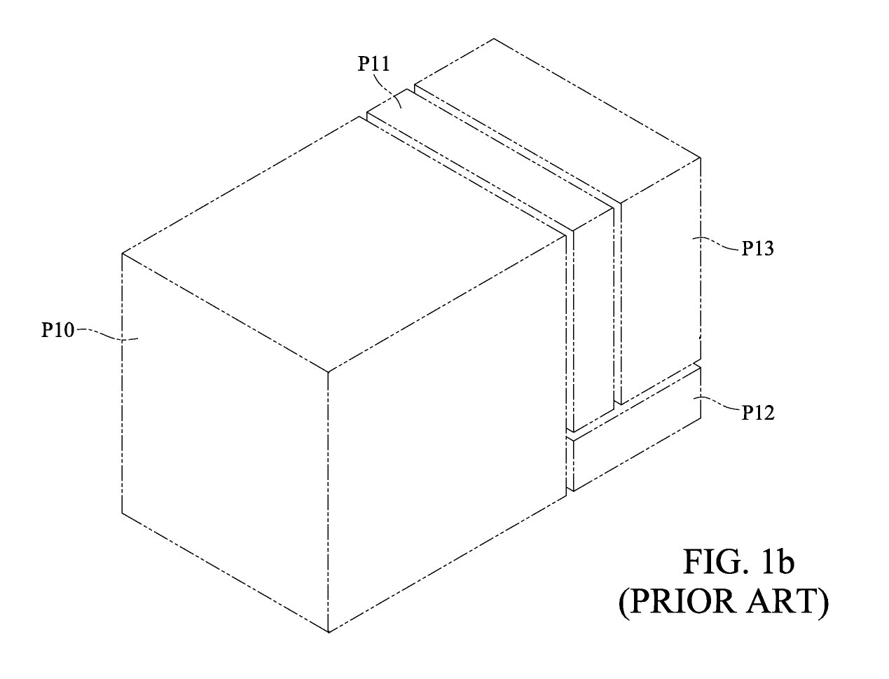

FIG. 2a shows an explanatory diagram for the hardware architecture of a 8-way system in the prior art.

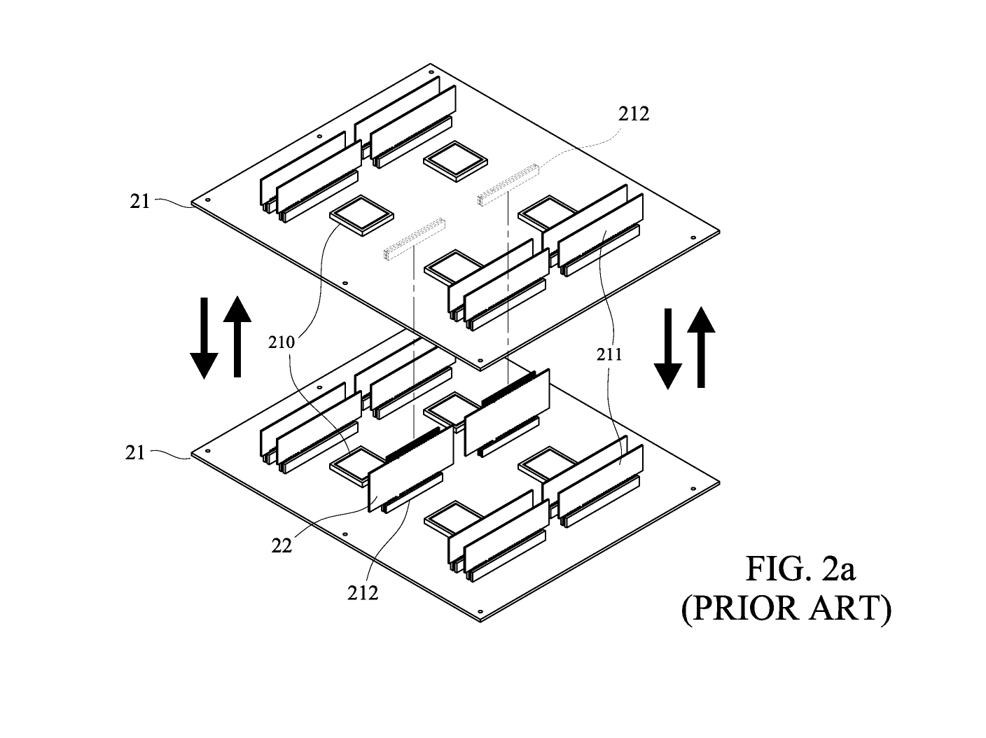

FIG. 2b shows an explanatory diagram of a chassis partition architecture according to FIG. 2a.

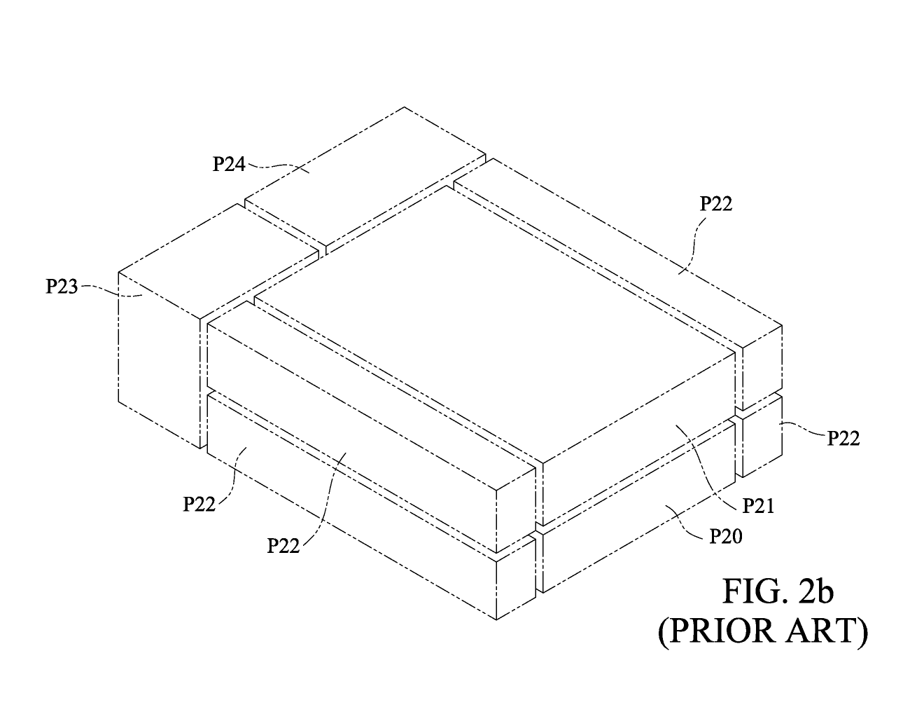

FIG. 3a shows an explanatory diagram for the hardware architecture of another 8-way system in the prior art.

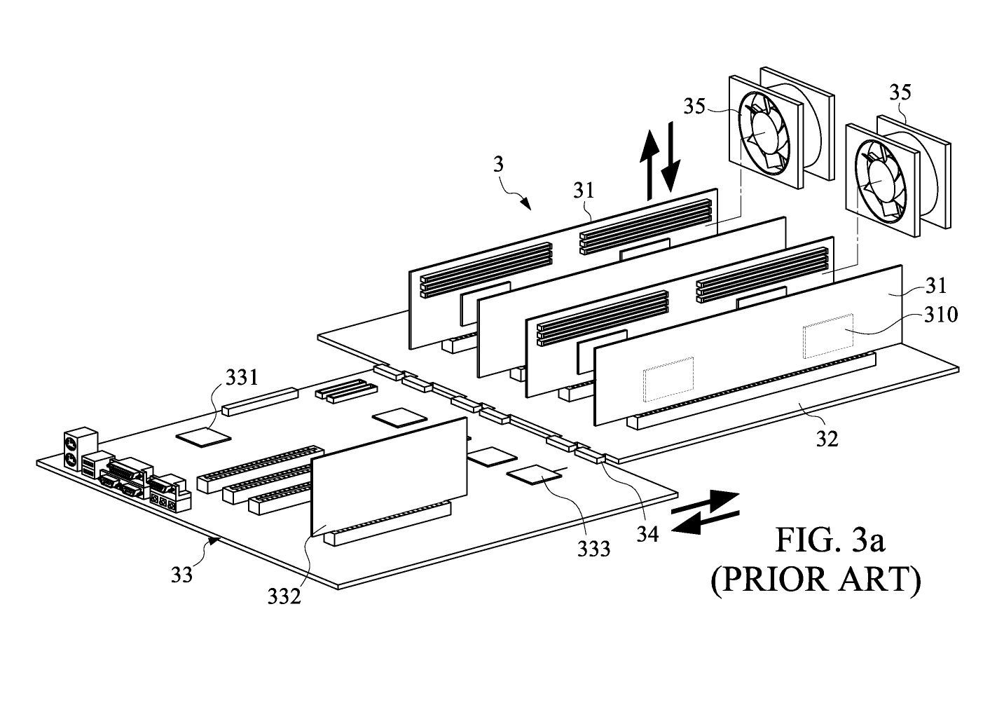

FIG. 3b shows an explanatory diagram of a chassis partition architecture according to FIG. 3a.

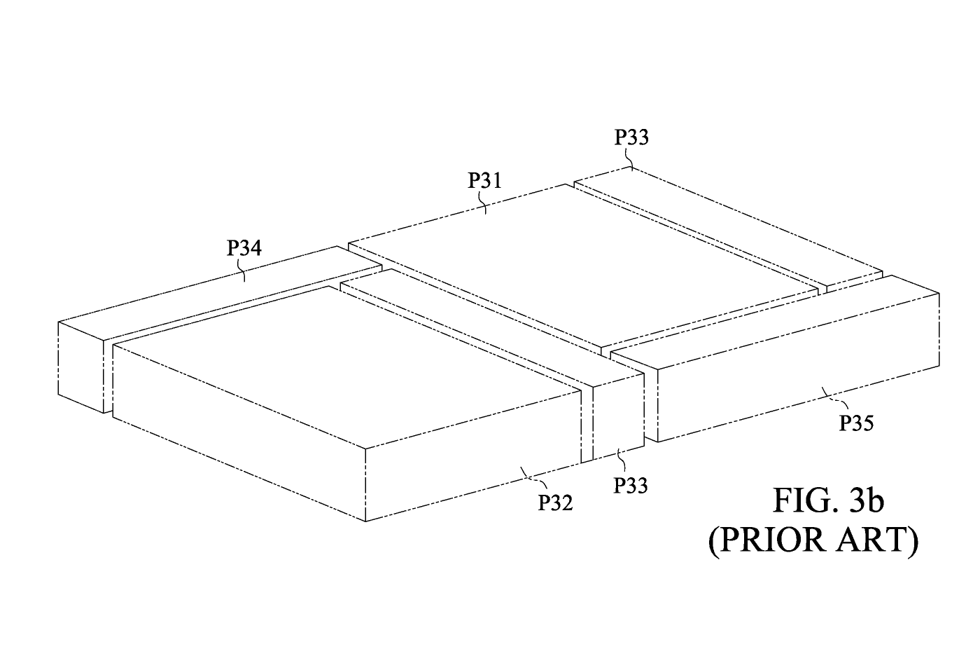

FIG. 4a shows an explanatory diagram of a chassis partition architecture for a multi-processor system according to an embodiment of the present invention.

FIG. 4b shows an explanatory diagram of a multidirectional configurable hardware architecture according to FIG. 4a.

FIG. 5a shows an explanatory diagram of a chassis partition architecture for a multi-processor system according to an embodiment of the present invention.

FIG. 5b shows an explanatory diagram of a multidirectional configurable hardware architecture according to FIG. 5a.

### DETAILED DESCRIPTION OF THE INVENTION

To achieve outstanding serviceability, configurability and cooling performance of a multi-processor system, a partition-oriented chassis design according to the present invention is provided under some hardware limitations.

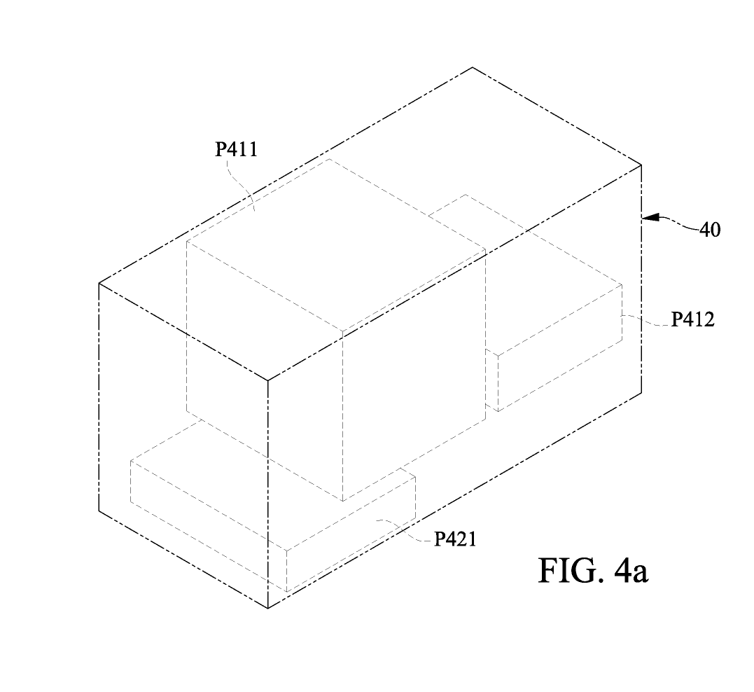

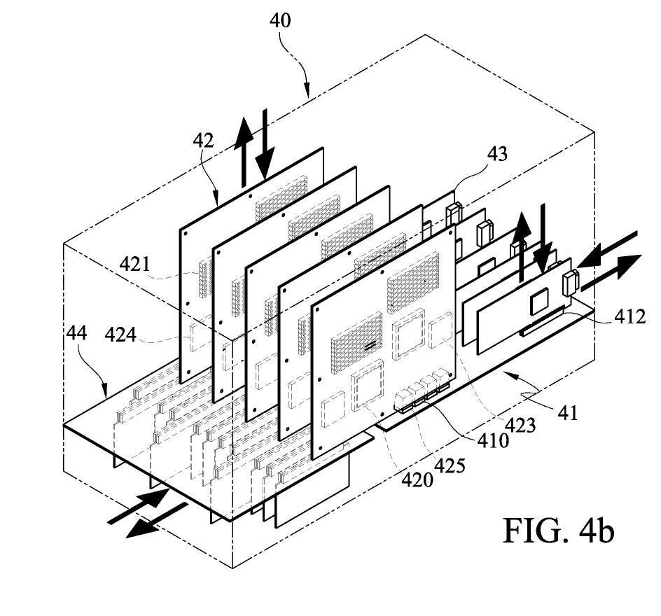

Please refer to FIGS. 4a and 4b. A partition architecture of a chassis 40 according to an embodiment of the present invention mainly includes a node partition P411, a expansion partition 412 and a function partition 421. Such partition architecture is designed dedicatedly for a multi-processor system with plural boards and numerous cards shown in FIG. 4b. The term “partition” herein is defined as an internal space of the chassis with no limitations to the mechanical construction.

The multi-processor system mainly includes a chassis 40, a bottom plane 41, plural processor boards 42, plural expansion cards 43, a function board 44 and plural function cards 45 and 46.

Basically, the node partition P411 is located at a middle section of the chassis 40 for containing the processor boards 42 configured vertically and lengthwise. The expansion partition P412 is located behind the node partition P411 for containing the expansion boards configured vertically and lengthwise. And the function partition 421 is located at a front section of the chassis 40 and lower than the node partition and the expansion partition. The function partition 421 is mainly to contain the function cards 45, 46 that are configured upside-down vertically and lengthwise.

For convenience of explanation, the physical structure of the chassis 40 is omitted in the drawings. The chassis 40 includes necessary frameworks and housings to provide reliable mechanical supports to the bottom plane 41, the processor boards 42, the expansion cards 43, the function board 44, the function cards 45, 46 and other electrical assemblies, as well as said partitions. To provide multidirectional configurability or serviceability, necessary openings and related slide modules will also be predetermined for the chassis 40.

The bottom plane 41 is configured horizontally and facing upwards at the rear lower section of the chassis 40. Namely, the bottom plane 41 is located under the node partition P411 and the expansion partition P412. The bottom plane 41 mainly includes plural system connectors 410 (such as FCI Airmax connectors) at its front section for connecting with the processor boards 42 in the node partition P411. Plural front edge connectors 411 (such as FCI Airmax connectors) located at the bottom surface and the front edge of the bottom plane 41 are used to connect the bottom plane 41 and the function board 44 edge-to-edge. In another word, the bottom plane 41 is in an edge-to-edge connection with the function board 44. At the rear section of the bottom plane 41, plural expansion connectors 412 (such as PCI-Express connectors) are configured to allow expansion cards 43 in the expansion partition P412 inserting therein. The bottom plane 41 in the embodiment is basically the major body of the entire hardware system. Almost every other units or modules are connected to the bottom plane 41, directly or indirectly. The service directions of the bottom plane 41 may be the laterals (left or right) and the rear. It will be configured into the chassis 40 first and become the last serviceable. In certain conditions, the bottom plane 41 may be configured on a slide tray for configuration convenience.

Additionally, the node partition P411 may exceed to reach the top of the function partition P421. Namely the bottom plane 41 may be shorter and make parts of the processor boards 42 exceed the front edge of the bottom plane 41 and reach the top of the function board 44. Such design will shorten the length of the node partition P11 or the bottom plane 41 and save space for the function board 44 or the function partition P421, thereby achieving an optimum space arrangement and a compact architecture.

In the node partition P411, each of the processor boards 42 mainly includes two processors 420, memories 421, a bridge chip(s) 423 (like North Bridge or South Bridge) and a BMC (Baseboard Management Controller) 424. Several bottom edge connectors 425 (such as FCI Airmax connectors) are configured at the bottom edges of the processor boards 42 to connect the system connectors 410 and stand vertically on the bottom plane 41. The processor boards 42 are allowed mounting/demounting or being serviceable or configurable from the top side. Some slide tray module (not shown) may be applied to every processor board 42. In certain cases, the five processor boards operate as one head node and four compute nodes.

Basically, in the expansion partition P412 the expansion cards 43 are configured parallel to the processor boards 42. These expansion cards 43 in the embodiment are serviceable or configurable from the top side or the rear side. In some cases, the expansion cards are network cards (such as InfiniBand or Ethernet cards), audio cards or graphic cards. It is possible that the expansion cards 43 are inserted into the expansion connectors 412 first before configuring the bottom plane 41 into the chassis 40.

Between the node partition P411 and the function partition P421, the function board 44 is configured facing downwards and connecting with the front edge connector 411 of the bottom plane 41 through its rear edge connectors 442 (such as FCI Airmax connectors) located at its rear edge and bottom surface. Plural function connectors 442 are also configured on the bottom surface of the function board 44 to connect with plural function cards 45, 46. Limited by the connecting direction, the function board 44 is serviceable or configurable from the front side.

The function cards 45, 46 in the function partition P421 are configured parallel to the processor boards 42 or the expansion cards 43. The function cards 45, 46 in the embodiment are serviceable or configurable from the bottom side. In some cases, the function cards 45, 46 are network cards (such as InfiniBand or Ethernet cards), audio cards or graphic cards. Of course the function cards 45, 46 may be inserted into the function connectors 442 first before connecting the function board 44 with the bottom plane 41.

The chassis partition architecture disclosed above provides multidirectional serviceability and configurability for a multi-processor system. Such architecture might require a cooling system to provide two airflows; one for the node partition 411 and the expansion partition P412 and the other for the function partition P421.

If the function partition P421 is located in front of the node partition P411 (the sequence of the partitions will be Function-Node-Expansion), namely the function board 44 is configured facing upwards with the function cards 45, 46 standing vertically and lengthwise, the overall length will be too long to dissipate heat efficiently.

Meanwhile, if the function partition P421 is located behind the expansion partition P412 (the sequence of the partitions will be Node-Expansion-Function), namely the function board 44 is configured next to the rear edge of the bottom plane 41, the communication path between the processor boards 42 and the function cards 45, 46 will be too long to fulfill the requirement of high data communication speed. Such architecture has a long overall length and the inefficient cooling problem as well.

If the function partition P421 is located adjacent to the lateral sides (the left or right sides) of the node partition P411, namely the function board 44 is configured next to one of the lateral sides of the bottom plane 41 and make the function cards 45, 46 aligned parallel to the expansion cards 43, the communication path may not be too long. However, the cooling solution will be difficult for the function board 44 and the function cards 45, 46. Theoretically extra fans will be required to provide cooling airflow dedicatedly for the function partition P421. Besides, the arrangements of other modules or units like hard drives and power supplies might become cooling blockage of the function cards 45, 46.

If the partitions remain the same but the function board 44 and the bottom plane 41 are combined as one board, such system will be lack of flexibility because the function cards will not allow changing specifications.

Therefore, the disclosed way to partition the chassis and the whole system also contributes an optimized architecture to facilitate outstanding hardware performance, serviceability, flexibility and cooling capability.

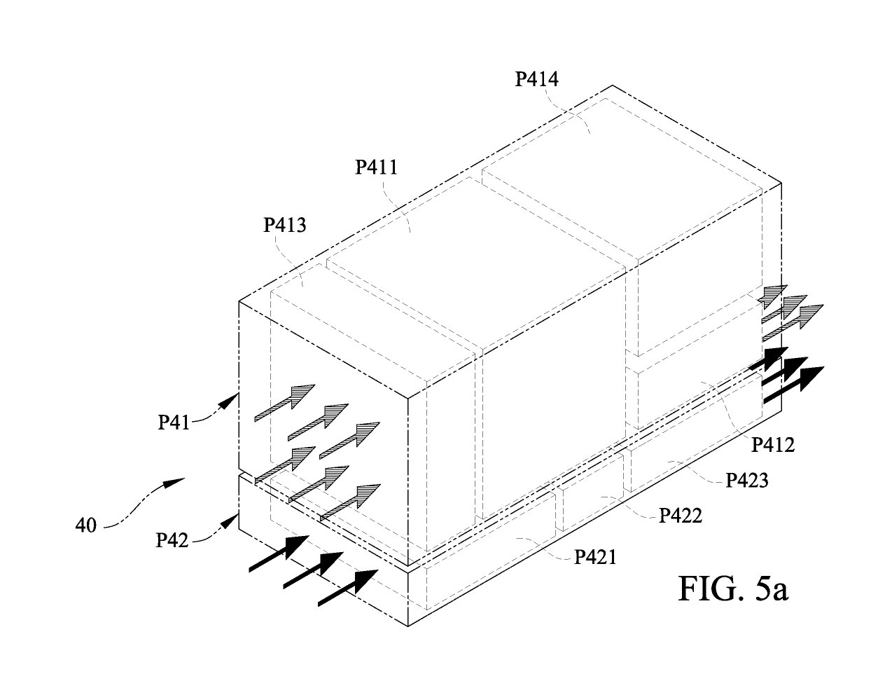

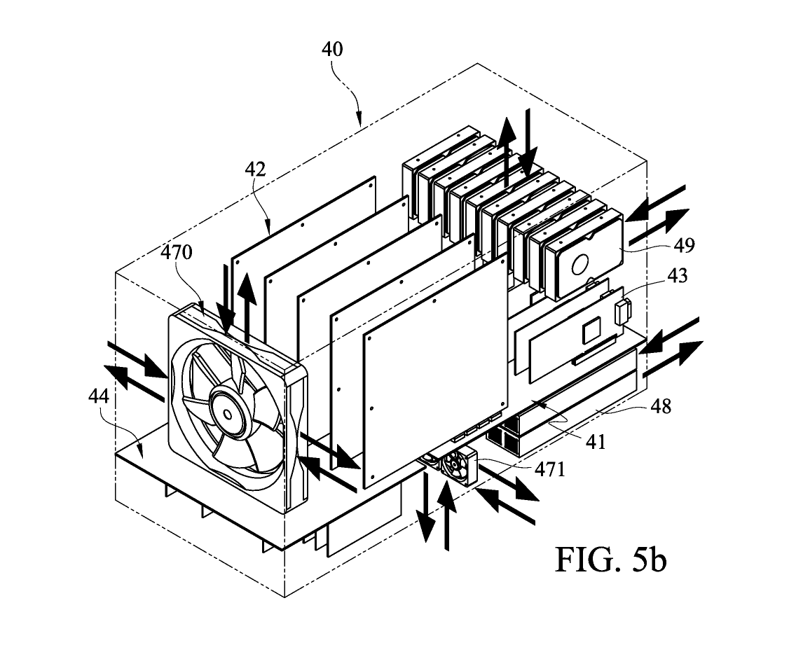

Please refer to FIGS. 5a and 5b. Another embodiment of the present invention presents an optimum partition architecture for a complete multi-processor system. The main units remain the same as shown in FIGS. 4a and 4b, including the node partition P411, the expansion partition 412 and the function partition P421 with the bottom plane 41, the processor boards 42, the expansion cards 43, the function board 44 and the function cards 45 and 46.

The present architecture includes two spaces with dedicated cooling airflows. A main space P41 at the upper location includes a main-fan partition P413, the node partition P411, a storage partition P414 and the expansion partition 412. The node partition P411 is mainly located at the middle section of the main space P41. The main-fan partition P413 is located right in front of the node partition P411 for containing main system fan(s) 470. The storage partition P414 is located behind the node partition and on the top of the expansion partition for containing plural hard drives 49.

A sub-space P42 at the lower location (or under the main space P41) includes the function partition P421, a sub-fan partition P422 and a power partition P423. The function is mainly located at the front section of the function partition P421. The sub-fan partition P422 is located behind the expansion partition P421 for containing auxiliary system fan(s) 471. And the power partition P423 is located behind the sub-fan partition P422 for containing plural power supply 48.

One of the two airflows is generated by the main system fan 470 in the main-fan partition P413 and passes through every partitions of the main space P41. The other airflow is mainly generated by the auxiliary system fan 471 in the sub-fan partition P422 and passes through every partitions of the sub-space P42.

As to related hardware configuration, the choices of the main system fan 470 may be one large, quite fan or four smaller fans; either may be configured in front of the bottom plane 41 and also on the top of the function board 44. The one or more main system fan 470 is serviceable or configurable from the top side or the lateral sides.

Plural hard drives 49 may be configured on the top of the expansion cards 43 and may reserve sufficient space under the hard drives 49 for the upper airflow. In certain cases, no reserved space is required because the expansion cards 43 are the major heat-generating sources. The processors 420 may be configured on the lower section of the processor boards 42 to align with said reserved space and/or the expansion cards 43. The hard drives 49 are also serviceable or configurable from the top side or the read side.

The auxiliary system fan 471 (possibly with smaller size) is configured under the bottom plane 41 and located between the function cards 45, 46 and the power supplies 48. If the function cards 45, 46 and the expansion cards 43 generates different amount of heat, the cards that generates more heat may be arranged at the upper airflow channel, namely the main space P41. The plural power supplies 48 with dedicated fans may be configured under the rear section of the bottom plane 41. If the function cards 45, 46 generate less heat, the dedicated fans of the power supplies and the smaller auxiliary system fan(s) will provide enough airflow.

The auxiliary system fan(s) 471 will be serviceable or configurable from the bottom side or the lateral sides. As to the power supplies 48, generally the rear side is enough for service or configuration.

In short, FIGS. 5a and 5b shows a partition architecture with bi-path cooling corresponding to the hardware architecture of the multi-processor system. Not only flexibility, serviceability and configurability are provided, a optimum cooling capability is accomplished as well.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A partition architecture of a chassis for configuring a multi-processor system, comprising:
a node partition located at a middle section of the chassis for containing a plurality of processor boards configured vertically and lengthwise;
a expansion partition located behind the node partition for containing a plurality of expansion boards configured vertically and lengthwise; and
a function partition located at a front section of the chassis lower than the node partition and the expansion partition for containing a plurality of function cards configured upside-down vertically and lengthwise.

2. The architecture of claim 1, wherein a bottom plane of the multi-processor system facing upwards and is configured under the node partition and the expansion partition to allow the processor boards and the expansion cards connecting thereon.

3. The architecture of claim 2, wherein a function board facing downwards is configured in an edge-to-edge connection with a front edge of the bottom plane to allow the function cards configured downwards and lengthwise on a bottom surface of the function board.

4. The architecture of claim 1, wherein the node partition exceeds to reach the top of the function partition.

5. The architecture of claim 1 further comprising a main space and an sub-space, each provided with a dedicated airflow, wherein the main space comprises the node partition and the expansion partition and the sub-space comprises the function partition.

6. The architecture of claim 5, wherein the main space further comprises a main-fan partition located right in front of the node partition for containing at least one main system fan.

7. The architecture of claim 5, wherein the main space further comprises a storage partition located behind the node partition and on the top of the expansion partition for containing a plurality of hard drives.

8. The architecture of claim 5, wherein the sub-space further comprises a sub-fan partition located behind the function partition for containing at least one auxiliary system fan.

9. The architecture of claim 8, wherein the sub-space further comprises a power partition located behind the sub-fan partition for containing a plurality of power supplies.

10. A partition architecture of a chassis for configuring a multi-processor system, comprising:
a main space comprising a node partition and a expansion partition, the node partition being located at a middle section of the main space for containing a plurality of processor boards configured vertically and lengthwise, the expansion partition being located behind the node partition for containing a plurality of expansion boards configured vertically and lengthwise; and
a sub-space located under the main space, comprising a function partition located at a front section of the sub-space for containing a plurality of function cards configured upside-down vertically and lengthwise.

11. The architecture of claim 10, wherein a bottom plane of the multi-processor system facing upwards and is configured under the node partition and the expansion partition to allow the processor boards and the expansion cards connecting thereon.

12. The architecture of claim 11, wherein a function board facing downwards is configured in an edge-to-edge connection with a front edge of the bottom plane to allow the function cards configured downwards and lengthwise on a bottom surface of the function board.

13. The architecture of claim 10, wherein the node partition exceeds to reach the top of the function partition.

14. The architecture of claim 10, wherein each of the main space and the sub-space is provided with a dedicated airflow.

15. The architecture of claim 10, wherein the main space further comprises a main-fan partition located right in front of the node partition for containing at least one main system fan.

16. The architecture of claim 10, wherein the main space further comprises a storage partition located behind the node partition and on the top of the expansion partition for containing a plurality of hard drives.

17. The architecture of claim 10, wherein the sub-space further comprises a sub-fan partition located behind the function partition for containing at least one auxiliary system fan.

18. The architecture of claim 17, wherein the sub-space further comprises a power partition located behind the sub-fan partition for containing a plurality of power supplies.
